(19) United States
(12) Patent Application Publication
(10) Pub. No.: US 2026/0361275 A1
(43) Pub. Date: Nov. 12, 2026

(54) SIGNAL DRIVER INCLUDING PARALLEL SETS OF CASCADED AMPLIFIERS WITH CROSS-CURRENT CONTROL

(71) Applicant: QUALCOMM Incorporated, San Diego, CA (US)

(72) Inventor: Vijayakumar DHANASEKARAN, San Diego, CA (US)

(21) Appl. No.: 19/205,722

(22) Filed: May 12, 2025

(51) Int. Cl. H03F 1/30; H04R 5/04

(52) U.S. Cl. CPC H03F 1/304; H04R 5/04; H03F 2200/03; H03F 2200/372; H03F 2200/375

(57) ABSTRACT

A signal driver, including: a first set of amplifiers cascaded from a first signal input to a first signal output; a second set of amplifiers cascaded from a second signal input to a second signal output; a first switch device coupled between the first signal input and the second signal input; and a set of one or more switch devices coupled between one or more amplifiers of the first set and one or more amplifiers of the second set, respectively.

### FIELD

This disclosure relates generally to signal driver, and in particular, to a signal driver including parallel sets of cascaded amplifiers with cross-current control.

### BACKGROUND

In certain audio signal applications, a Bluetooth audio codec or micropower WiFi audio streaming provides an audio digital signal to a signal driver to generate an audio signal for driving one or more speakers. The signal driver may include a digital-to-analog converter (DAC) followed by a set of cascaded audio amplifiers to generate an audio signal for driving a speaker from the audio digital signal. Due to higher audio codec or streaming performance, the signal driver may be designed to provide an audio signal with minimal noise to the speaker.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a signal driver. The signal driver includes: a first set of amplifiers cascaded from a first signal input to a first signal output; a second set of amplifiers cascaded from a second signal input to a second signal output; a first switch device switch device coupled between the first signal input and the second signal input; and a set of one or more switch devices coupled between one or more amplifiers of the first set and one or more amplifiers of the second set, respectively.

Another aspect of the disclosure relates to a method of providing an output signal to a load. The method includes: amplifying an input signal using a first set of cascaded amplifiers to generate the output signal in accordance with a first mode of operation and a second mode of operation; amplifying the input signal using a second set of cascaded amplifiers to generate the output signal in accordance with the second mode of operation but not the first mode of operation; and coupling inputs and outputs of the first set of cascaded amplifiers to inputs and outputs of the second set of cascaded amplifiers in accordance with the second mode of operation, respectively.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a schematic diagram of an example signal driver in accordance with an aspect of the disclosure.

FIG. 2 illustrates a voltage offset equivalent circuit of an example signal driver in accordance with another aspect of the disclosure.

FIG. 3 illustrates a schematic diagram of another example signal driver in accordance with another aspect of the disclosure.

FIG. 4 illustrates a voltage offset equivalent circuit of an example signal driver in accordance with another aspect of the disclosure.

FIG. 5 illustrates a schematic diagram of another example signal driver in accordance with another aspect of the disclosure.

FIG. 6 illustrates a schematic diagram of another example signal driver in accordance with another aspect of the disclosure.

FIG. 7 illustrates a schematic diagram of another example signal driver in accordance with another aspect of the disclosure.

FIG. 8 illustrates an example method of providing a signal to a load in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

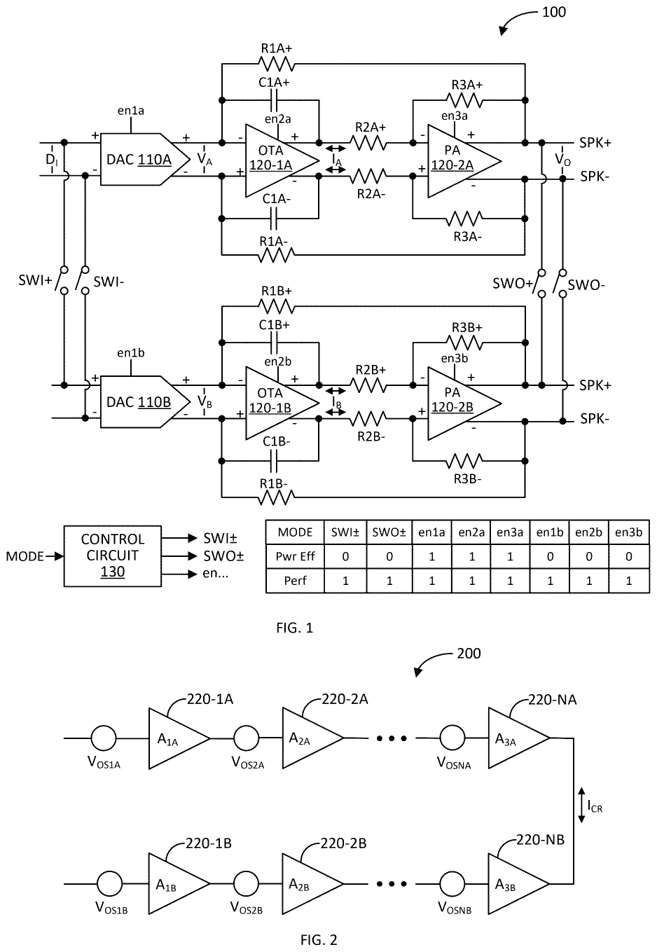

FIG. 1 illustrates a schematic diagram of an example signal driver 100 in accordance with an aspect of the disclosure. The signal driver 100 is configured to receive an input digital audio signal D_{I}, and generate therefrom, an analog audio signal V_{O} for driving a speaker (e.g., an earbud speaker or other type of speaker). Although processing of audio signals is used to exemplify the concepts described herein, it shall be understood that the concepts described herein may be extended to other types of signals. The input audio signal D_{I} may be generated by a Bluetooth audio codec or a micropower WiFi audio streaming system. Due to their high audio performance, the signal driver 100 may include at least two modes of operations: a power efficient mode for battery power savings and a high-performance mode for higher audio quality.

In particular, the signal driver 100 includes a first parallel audio path “A” including a digital-to-analog converter (DAC) 110A, an operational transconductance amplifier (OTA) 120-1A including differential feedback capacitors C1A+/C1A−, a power amplifier (PA) 120-2A including differential input resistors R2A+/R2A− and differential feedback resistors R3A+/R3A−, and differential feedback resistors R1A+/R1A− associated with both the OTA 120-1A and the PA 120-2A.

The DAC 110A includes a differential input +/− configured to receive an input differential (e.g., audio) digital signal D_{I}. The DAC 110A may include an enable control input configured to receive an enable control signal en1a. If the enable control signal en1a is asserted (e.g., en1a=1), the DAC 110A is configured to convert the input differential digital signal D_{I} into an analog differential voltage signal V_{A}. The analog differential voltage signal V_{A} is generated at a differential output +/− of the DAC 110A. The differential output +/− of the DAC 110A is coupled to a differential input −/+ of the OTA 120-1A. If the enable control signal en1a is deasserted (e.g., en1a=0), the DAC 110A may be disabled.

With regard to the OTA 120-1A, the differential feedback capacitor C1A+ is coupled between a positive (+) differential output and a negative (−) differential input of the OTA 120-1A. The differential feedback capacitor C1A− is coupled between a negative (−) differential output and a positive (+) differential input of the OTA 120-1A. The differential resistor R1A+ is coupled between a positive (+) differential output of the PA 120-2A and the negative (−) differential input of the OTA 120-1A. The differential resistor R1A− is coupled between a negative (−) differential output of the PA 120-2A and the positive (+) differential input of the OTA 120-1A. The OTA 120-1A may also include an enable control input configured to an enable control signal en2a. If the enable control signal en2a is asserted (e.g., en2a=1), the OTA 120-1A is configured to amplify the analog differential voltage signal V_{A} to generate an analog differential current signal I_{A} at the differential output +/− thereof. If the enable control signal en2a is deasserted (e.g., en2a=0), the OTA 120-1A may be disabled.

With regard to the PA 120-2A, the differential input resistor R2A+ is coupled between the positive (+) differential output of the OTA 120-1A and the negative (−) differential input of the PA 120-2A. The differential input resistor R2A− is coupled between the negative (−) differential output of the OTA 120-1A and the positive (+) differential input of the PA 120-2A. The differential feedback resistor R3A+ is coupled between the positive (+) differential output and the negative (−) differential input of the PA 120-2A. The differential feedback resistor R3A− is coupled between the negative (−) differential output and the positive (+) differential input of the PA 120-2A. The PA 120-2A may also include an enable control input configured to receive an enable control signal en3a. If the enable control signal en3a is asserted (e.g., en3a=1), the PA 120-2A is configured to amplify the analog differential current signal I_{A} to generate an output differential voltage signal V_{O} at the differential output +/− thereof. The differential output +/− of the PA 120-2A is coupled to positive (SPK+) and negative (SPK−) terminals of a speaker. If the enable control signal en3a is deasserted (e.g., en3a=0), the PA 120-2A may be disabled.

The signal driver 100 further includes a second parallel audio path “B” including a DAC 110B, an OTA 120-1B including differential feedback capacitors C1B+/C1B−, a PA 120-2B including differential input resistors R2B+/R2B− and differential feedback resistors R3B+/R3B−, and differential feedback resistors R1B+/R1B− associated with both the OTA 120-1B and the PA 120-2B.

The signal driver 100 further includes input differential switch devices SWI+/SWI− and output differential switch devices SWO+/SWO−. The input differential switch devices SWI+/SWI− are coupled between the differential input +/− of the DAC 110A of the first parallel audio path “A” and a differential input +/− of the DAC 110B of the second parallel audio path “B”. The output differential switch devices SWO+/SWO− are coupled between the differential output +/− of the PA 120-2A of the first parallel audio path “A” and a differential output +/− of the PA 120-2B of the second parallel audio path “B”.

When the input differential switch devices SWI+/SWI− are closed (e.g., turned on if implemented as digital multiplexer or field effect transistor (FET) type devices), the DAC 110B is configured to receive the input differential digital signal D_{I} via the input differential switch devices SWI+/SWI−. The DAC 110B may also include an enable control input configured to receive an enable control signal en1b. If the enable control signal en1b is asserted (e.g., en1b=1), the DAC 110B is configured to convert the input differential digital signal D_{I} into an analog differential voltage signal V_{B}. The analog differential voltage signal V_{B} is generated at a differential output +/− of the DAC 110B. The differential output +/− of the DAC 110B is coupled to a differential input −/+ of the OTA 120-1B. If the enable control signal en1b is deasserted (e.g., en1b=0), the DAC 110B may be disabled.

With regard to the OTA 120-1B, the differential feedback capacitor C1B+ is coupled between a positive (+) differential output and a negative (−) differential input of the OTA 120-1B. The differential feedback capacitor C1B− is coupled between a negative (−) differential output and a positive (+) differential input of the OTA 120-1B. The differential resistor R1B+ is coupled between a positive (+) differential output of the PA 120-2B and the negative (−) differential input of the OTA 120-1B. The differential resistor R1B− is coupled between a negative (−) differential output of the PA 120-2B and the positive (+) differential input of the OTA 120-1B. The OTA 120-1B may also include an enable control input configured to receive an enable control signal en2b. If the enable control signal en2b is asserted (e.g., en2b=1), the OTA 120-1B is configured to amplify the analog differential voltage signal V_{B} to generate an analog differential current signal I_{B} at the differential output +/− thereof. If the enable control signal en2b is deasserted (e.g., en2b=0), the OTA 120-1B may be disabled.

With regard to the PA 120-2B, the differential input resistor R2B+ is coupled between the positive (+) differential output of the OTA 120-1B and the negative (−) differential input of the PA 120-2B. The differential input resistor R2B− is coupled between the negative (−) differential output of the OTA 120-1B and the positive (+) differential input of the PA 120-2B. The differential feedback resistor R3B+ is coupled between the positive (+) differential output and the negative (−) differential input of the PA 120-2B. The differential feedback resistor R3B− is coupled between the negative (−) differential output and the positive (+) differential input of the PA 120-2B. The PA 120-2B may also include an enable control input configured to receive an enable control signal en3b. If the enable control signal en3b is asserted (e.g., en3b=1) and the output differential switch devices SWO+/SWO− are closed (e.g., turned on if implemented as FET type devices), the PA 120-2B is configured to amplify the analog differential current signal I_{B} to generate the output differential voltage signal V_{O} at both differential outputs+/− of the PAs 120-2A and 120-2B. If the enable control signal en3b is deasserted (e.g., en3b=0), the PA 120-2B may be disabled. The differential output +/− of the PA 120-2B may also be coupled to the positive (SPK+) and negative (SPK−) terminals of the speaker.

The signal driver 100 further includes a control circuit 130 configured to generate control signals for the input differential switch devices SWI+/SWI− and the output differential switch devices SWO+/SWO−, and the enable signals en1a/en1b to en3a/en3b based on a mode of operation.

With reference to a mode table also depicted in FIG. 1, if the mode of operation is a power efficient mode, the control circuit 130 is configured to open or turn off the input differential switch devices SWI+/SWI− and the output differential switch devices SWO+/SWO− (e.g., SWI+/SWI−=SWO+/SWO=0/0), deassert the enable signals en1b, en2b, and en3b (e.g., en1b=en2b=en3b=0), and assert the enable signals en1a, en2a, and en3a (e.g., en1a=en2a=en3a=1). Accordingly, in the power efficient mode, the first audio path “A” is enabled and the second audio path “B” is disabled. As such, power savings occur due to the second audio path “B” being turned off.

If the mode of operation is a performance mode, the control circuit 130 is configured to close or turn on the input differential switch devices SWI+/SWI− and the output differential switch devices SWO+/SWO− (e.g., SWI+/SWI−=SWO+/SWO−=1/1), assert the enable signals en1b, en2b, and en3b (e.g., en1b=en2b=en3b=1), and assert the enable signals en1a, en2a, and en3a (e.g., en1a=en2a=en3a=1). Accordingly, in the performance mode, both the first and second audio paths “A” and “B” are enabled. As such, a higher signal-to-noise (SNR) signal V_{O} is provided to the speakers due to the effective impedance of the parallel-coupled first and second audio paths “A” and “B” being reduced compared to the effective impedance of only the first audio path “A”.

FIG. 2 illustrates a voltage offset equivalent circuit 200 of an example signal driver in accordance with another aspect of the disclosure. The signal driver 100 may be a specific example of the voltage offset equivalent circuit 200. The voltage offset equivalent circuit 200 includes a first audio signal path “A” including a set of cascaded amplifiers 220-1A to 220-NA, where “N” is an integer of two or more. The voltage offset equivalent circuit 200 includes a second audio signal path “B” including a set of cascaded amplifiers 220-1B to 220-NB. The output of the first and second audio signal paths “A” and “B” are coupled together.

Due to mismatches between the amplifiers 220-1A to 220-NA of the first audio path “A” and the amplifiers 220-1B to 220-NB of the second audio path “B”, offset voltages V_{OS1A} to V_{OSNA} developed at the inputs of the amplifiers 220-1A to 220-NA are different than offset voltages V_{OSIB} to V_{OSNB} developed at the inputs of the amplifiers 220-1B to 220-NB, respectively. As a result of the differences in the offset voltages, a cross current I_{CR} is generated at the outputs of the amplifiers 220-NA and 220-NB. The cross current I_{CR} causes large power wastage without corresponding payback in SNR or other performance improvements.

The cross current I_{CR} may be approximated by equation one (Eq. 1) as follows:

$${I}_{Cr} = ( {\sum }_{n = 1}^{N - 1} {V}_{{Os}_{n , A}^{*}} {\prod }_{m = n}^{N - 1} {A}_{m , A} + VosN , A ) * {G}_{m , NA} - ( {\sum }_{n = 1}^{N - 1} {V}_{{Os}_{n , B}^{*}} {\prod }_{m = n}^{N - 1} {A}_{m , B} + VosN , B ) * {G}_{m , NB}$$

### Where

$${V}_{{Os}_{n , A}^{*}}$$

is the n^{th} stage voltage of the first audio path “A”,

$${V}_{{Os}_{n , B}^{*}}$$

is the n^{th} offset voltage of the second audio path “B”, A_{m,A} is the gain of the m^{th} stage amplifier 220-mA of the first audio path “A”, A_{m,B} is the gain of the m^{th} stage amplifier 220-mB of the second audio path “B”, VOsN, A is the offset voltage contribution of the last amplifier 220-NA of the first audio path “A”, VOsN, B is the offset voltage contribution of the last amplifier 220-NB of the second audio path “B”, G_{m,NA} is the transconductance gain of the last amplifier 220-NA of the first audio path “A”, and G_{m,NB} is the transconductance gain of the last amplifier 220-NB of the second audio path “B”. Note, that according to Eq. 1, the contribution to the cross current I_{CR} is more prevalent for the voltage offset differences closer to the input than those closer the output due to gain accumulation towards the output of the voltage offset equivalent circuit 200.

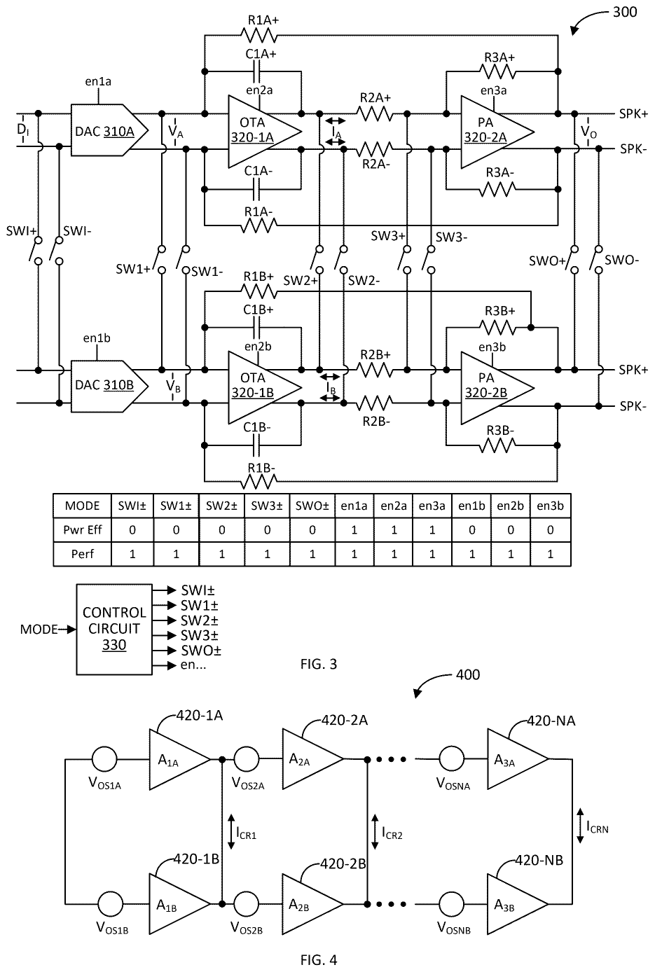

FIG. 3 illustrates a schematic diagram of another example signal driver 300 in accordance with another aspect of the disclosure. The signal driver 300 is similar to the signal driver 100 including many of the same/similar elements as indicated by the same reference identifiers and numbers with the exception that their most significant digit is a “3” for signal driver 300 instead of a “1” for signal driver 100.

To reduce the cross current I_{CR} generated at the outputs of the first and second audio paths A/B due to differences in offset voltages at the inputs and outputs of the OTAs 320-1A/320-1B, the signal driver 300 further includes intermediate differential switch devices SW1+/SW1− and SW2+/SW2− coupled between the differential inputs +/− and outputs +/− of the OTAs 320-1A and 320-1B, respectively. Also, to reduce the cross current I_{CR} generated at the outputs of the first and second audio paths A/B due to differences in offset voltages at the inputs of the PAs 320-2A/320-2B, the signal driver 300 further includes intermediate differential switch devices SW3+/SW3− coupled between the differential inputs +/− of the PAs 320-2A and 320-2B, respectively. The control circuit 330 is configured to control the closed/open (on/off) states of the intermediate differential switch devices SW1+/SW1−, SW2+/SW2−, and SW3+/SW3− based on a mode of operation.

With reference to a mode table also depicted in FIG. 3, if the mode of operation is the power efficient mode, the control circuit 330 may be configured to open or turn off the differential switch devices SWI+/SWI−, SW1+/SW1−, SW2+/SW2−, and SW3+/SW3−, and SWO+/SWO− (e.g., SWI+/SWI−=SW1+/SW1−=SW2+/SW2−=SW3+/SW3−=SWO+/SWO−=0/0), deassert the enable signals en1b, en2b, and en3b (e.g., en1b=en2b=en3b=0), and assert the enable signals en1a, en2a, and en3a (e.g., en1a=en2a-en3a=1). Accordingly, similar to signal driver 100, in the power efficient mode, the first audio path “A” is enabled and the second audio path “B” is disabled. As such, power savings occur due to the second audio path “B” being turned off.

If the mode of operation is a performance mode, the control circuit 330 may be configured to close or turn on the differential switch devices SWI+/SWI−, SW1+/SW1−, SW2+/SW2−, and SW3+/SW3−, and SWO+/SWO− (e.g., SWI+/SWI−=SW1+/SW1−=SW2+/SW2−=SW3+/SW3−=SWO+/SWO−=1/1), assert the enable signals en1b, en2b, and en3b (e.g., en1b=en2b=en3b=1), and assert the enable signals en1a, en2a, and en3a (e.g., en1a=en2a=en3a=1). Accordingly, in the performance mode, both the first and second audio paths “A” and “B” are enabled. Further, due to the intermediate switch devices SW1+/SW1−, SW2+/SW2−, and SW3+/SW3− being closed (on), differences in offset voltages at the inputs and outputs of the OTAs 320-1A/320-1B are substantially eliminated. Thus, the parallel coupling of the first and second audio paths “A” and “B” and the elimination of the offset voltages prevent power wastage due to large cross current I_{CR}.

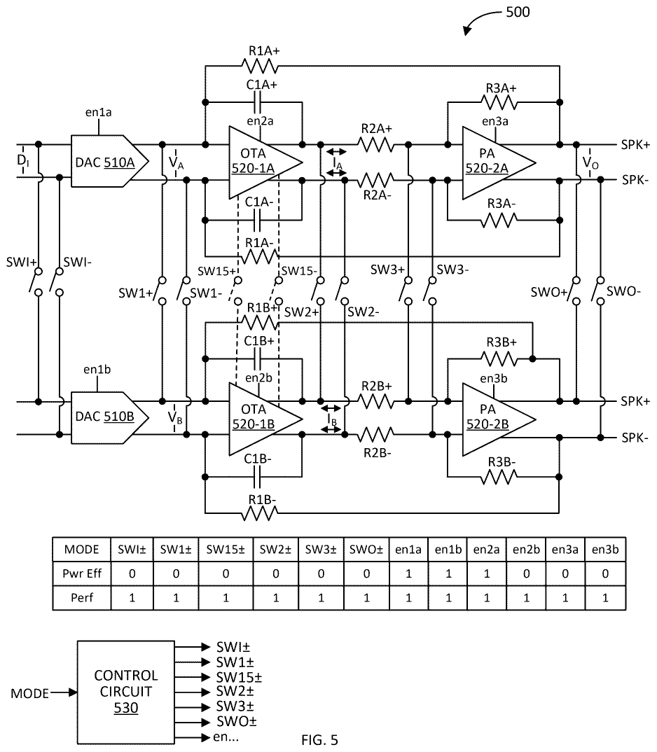

FIG. 4 illustrates a voltage offset equivalent circuit 400 of an example signal driver in accordance with another aspect of the disclosure. The signal driver 300 may be a specific example of the voltage offset equivalent circuit 400. The voltage offset equivalent circuit 400 includes a first audio path “A” including a set of cascaded amplifiers 420-1A to 420-NA, where “N” is an integer of two or more. The voltage offset equivalent circuit 400 includes a second audio path “B” including a set of cascaded amplifiers 420-1B to 420-NB. The inputs and outputs of the audio amplifiers 420-1A to 420-NA and 420-1B to 420-NB of the first and second audio paths “A” and “B” are coupled together via switch devices as discussed above with reference to signal driver 300, respectively.

As a result of the coupling together of the inputs and outputs of the amplifiers 420-1A to 420-NA and 420-1B to 420-NB, differences in the offset voltages at such inputs and outputs are substantially eliminated. The cross current I_{CRn} at the outputs of the n^{th} amplifiers 420-nA/420-nB may be approximated by equation two (Eq. 2) as follows:

$${I}_{Crn} = {V}_{{Os}_{n , A}^{*}} * {G}_{m , nA} - {V}_{{Os}_{n , B}^{*}} * {G}_{m , nB}$$

### Where

$${V}_{{Os}_{n , A}^{*}}$$

is the n^{th} stage offset voltage of the first audio path “A”,

$${V}_{{Os}_{n , B}^{*}}$$

is the n^{th} offset voltage of the second audio path “B”, G_{m,nA} is the transconductance gain of the n^{th} amplifier 420-nA of the first audio path “A”, and G_{m,nB} is the transconductance gain of the n^{th} amplifier 420-nB of the second audio path “B”. Note that the gain accumulation of the offset voltages is eliminated; thereby, reducing their contribution to the output cross current I_{CRN}.

FIG. 5 illustrates a schematic diagram of another example signal driver 500 in accordance with another aspect of the disclosure. The signal driver 500 may be a variation of signal driver 300 previously discussed. Accordingly, the signal driver 500 includes many of the same/similar elements as the signal driver 300 as indicated by the same reference identifiers and numbers with the exception that their most significant digit is a “5” for signal driver 500 instead of a “3” for signal driver 300.

The signal driver 500 differs from signal driver 300 in that the signal driver 500 includes additional differential switch devices SW15+/SW15− coupled between amplification stages within the OTAs 520-1A and 520-1B, respectively. In this case, difference in offset voltages between amplification stages may also accumulate in performance mode; and similarly, produce a greater cross current I_{CR} at the coupled outputs of the PAs 520-2A and 520-2B. As previously discussed, this increases power wastage due to the larger cross current I_{CR}. Accordingly, in performance mode, the control circuit 530 may be configured to close (turn on) the differential switch devices SW15+/SW15− to substantially eliminate the difference in the offset voltages to improve the SNR of the audio signal provided to the speaker. The states of the control signals in the power efficiency and performance modes are summarized in the table depicted in FIG. 5.

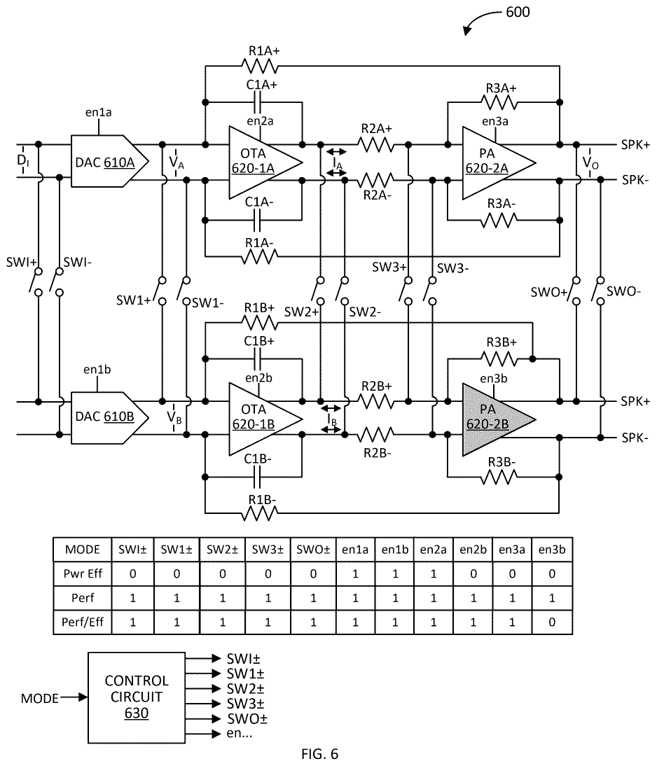

FIG. 6 illustrates a schematic diagram of another example signal driver 600 in accordance with another aspect of the disclosure. The signal driver 600 may be a variation of signal driver 500 previously discussed. Accordingly, the signal driver 600 includes many of the same/similar elements as the signal driver 500 as indicated by the same reference identifiers and numbers with the exception that their most significant digit is a “6” for signal driver 500 instead of a “5” for signal driver 500.

A difference between the signal driver 600 and signal driver 500 is that the signal driver 600 may have an additional modes of operation. For example, the signal driver 600 may have a hybrid mode of operation power efficiency/power between the power efficiency mode and the performance mode. The power efficiency/power mode is similar to the performance mode of signal driver 600 with the exception that the PA 620-2B is disabled (as indicated by its dark shading) to conserve power. Thus, the closed or turned on switch devices SWI+/SWI− SW1+/SW1−, and SW2+/SW2− substantially eliminate the differences in the offset voltages at the inputs and outputs of the OTAs 620-1A and 620-1B to reduce their degradation of the SNR of the output signal V_{O} provided to the speaker. The states of the control signals in the power efficiency, power efficiency/power, and performance modes are summarized in the table depicted in FIG. 6.

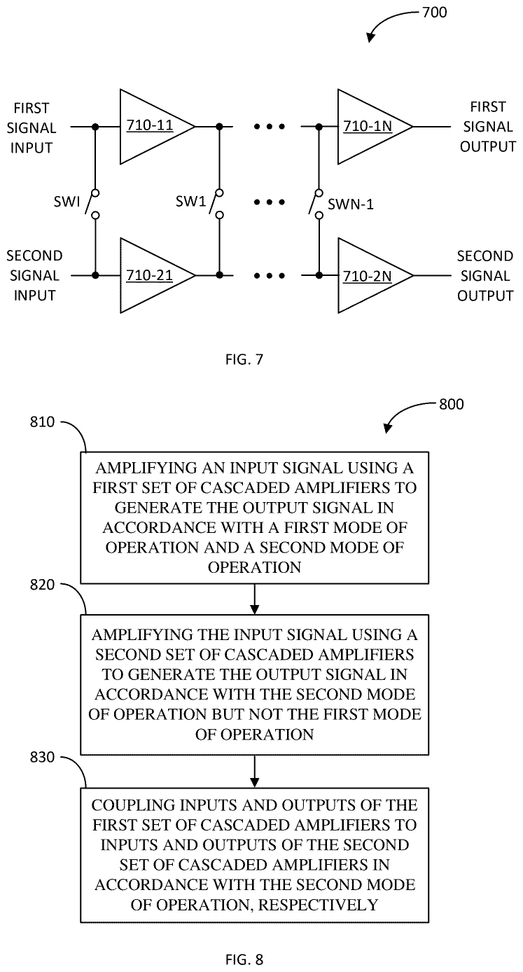

FIG. 7 illustrates a schematic diagram of another example signal driver 700 in accordance with another aspect of the disclosure. The signal driver 700 includes a first set of amplifiers 710-11 to 710-1N cascaded from a first signal input to a first signal output. The signal driver 700 further includes a second set of amplifiers 710-21 to 710-2N cascaded from a second signal input to a second signal output; a first switch device SWI coupled between the first signal input and the second signal input; and a set of one or more switch devices SW1 to SWN-1 coupled between one or more amplifiers of the first set 710-11 to 710-1N and one or more amplifiers of the second set 710-21 to 710-2N, respectively.

FIG. 8 illustrates an example method 800 of providing an output signal to a load in accordance with another aspect of the disclosure. The method 800 includes amplifying an input signal using a first set of cascaded amplifiers to generate the output signal in accordance with a first mode of operation and a second mode of operation (block 810). The method 800 further includes amplifying the input signal using a second set of cascaded amplifiers to generate the output signal in accordance with the second mode of operation but not the first mode of operation (block 820). Additionally, the method 800 includes coupling inputs and outputs of the first set of cascaded amplifiers to inputs and outputs of the second set of cascaded amplifiers in accordance with the second mode of operation, respectively (block 830).

The following provides an overview of aspects of the present disclosure:

Aspect 1: A signal driver, comprising: a first set of amplifiers cascaded from a first signal input to a first signal output; a second set of amplifiers cascaded from a second signal input to a second signal output; a first switch device coupled between the first signal input and the second signal input; and a set of one or more switch devices coupled between one or more amplifiers of the first set and one or more amplifiers of the second set, respectively.

Aspect 2: The signal driver of aspect 1, further comprising a control circuit configured to open or close the first switch device and the set of one or more switch devices in accordance with a first mode of operation or a second mode of operation, respectively.

Aspect 3: The signal driver of aspect 1 or 2, further comprising a second switch device coupled between the first signal output and the second signal output.

Aspect 4: The signal driver of aspect 3, further comprising a control circuit configured to open or close the first switch device, the second switch device, and the set of one or more switch devices in accordance with a first mode of operation or a second mode of operation, respectively.

Aspect 5: The signal driver of any one of aspects 1-4, wherein the second set of amplifiers includes a set of enable control inputs, respectively, and further comprising a control circuit configured to provide deasserted and asserted the set of enable control signals to the set of enable control inputs in accordance with a first mode of operation or a second mode of operation, respectively.

Aspect 6: The signal driver of any one of aspects 1-5, wherein: one of the first set of amplifiers comprises a first set of amplification stages; one of the second set of amplifiers comprises a second set of amplification stages; and further comprising a second switch device coupled between two of the first set of amplification stages and two of the second set of amplification stages.

Aspect 7: The signal driver of aspect 6, further comprising a control circuit configured to open or close the first switch device, the second switch device, and the set of one or more switch devices in accordance with a first mode of operation or a second mode of operation, respectively.

Aspect 8: The signal driver of any one of aspects 1-7, wherein: one of the first set of amplifiers comprises a first differential operational transconductance amplifier (OTA); one of the second set of amplifiers comprises a second differential OTA; and the first switch device comprises first differential switch devices coupled between a first differential input of the first differential OTA and a second differential input of the second differential OTA.

Aspect 9: The signal driver of aspect 8, wherein one of the set of one or more switch devices comprises second differential switch devices coupled between a first differential output of the first OTA and a second differential output of the second differential OTA.

Aspect 10: The signal driver of aspect 9, further comprising a control circuit configured to open or close the first and second differential switch devices in accordance with a first mode of operation or a second mode of operation, respectively.

Aspect 11: The signal driver of any one of aspects 1-10, wherein: one of the first set of amplifiers comprises a first power amplifier (PA); one of the second set of amplifiers comprises a second PA; and one of the set of one or more switch devices comprises first differential switch devices coupled between a first differential input of the first PA and a second differential input of the second PA.

Aspect 12: The signal driver of aspect 11, further comprising second differential switch devices coupled between a first differential output of the first PA and a second differential output of the second PA.

Aspect 13: The signal driver of anyone of aspects 1-12, further comprising: a first digital-to-analog converter (DAC) coupled between a first digital input and the first signal input; a second DAC coupled between a second digital input of the second signal input; and a second switch device coupled between the first digital input and the second digital input.

Aspect 14: The signal driver of aspect 13, further comprising a control circuit configured to open or close the first switch device, the second switch device, and the set of one or more switch devices in accordance with a first mode of operation or a second mode of operation, respectively.

Aspect 15: A method of providing an output signal to a load, comprising: amplifying an input signal using a first set of cascaded amplifiers to generate the output signal in accordance with a first mode of operation and a second mode of operation; amplifying the input signal using a second set of cascaded amplifiers to generate the output signal in accordance with the second mode of operation but not the first mode of operation; and coupling inputs and outputs of the first set of cascaded amplifiers to inputs and outputs of the second set of cascaded amplifiers in accordance with the second mode of operation, respectively.

Aspect 16: The method of aspect 15, further comprising decoupling the inputs and outputs of the first set of cascaded amplifiers from the inputs and outputs of the second set of cascaded amplifiers in accordance with the first mode of operation.

Aspect 17: The method of aspect 15 or 16, further comprising disabling the second set of cascaded amplifiers in accordance with the first mode of operation.

Aspect 18: The method of anyone of aspects 15-17, wherein a first last stage of the first set of cascaded amplifiers is enabled, and a second last stage of the second set of cascaded amplifiers is disabled in accordance with the second mode of operation.

Aspect 19: The method of anyone of aspects 15-18, further comprising coupling a first output of the first last stage of the first set of cascaded amplifiers to a second output of the second last stage of the second set of cascaded amplifiers in accordance with the second mode of operation.

Aspect 20: The method of anyone of aspects 15-19, wherein the input signal comprises an analog signal, and further comprising: converting a digital signal to generate at least a portion of the analog signal; and converting the digital signal to generate at least another portion of the analog signal.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples described herein but is to be accorded the widest scope consistent with the principles and novel features disclosed herein.

What is claimed:

1. A signal driver, comprising:
a first set of amplifiers cascaded from a first signal input to a first signal output;
a second set of amplifiers cascaded from a second signal input to a second signal output;
a first switch device coupled between the first signal input and the second signal input; and
a set of one or more switch devices coupled between one or more amplifiers of the first set and one or more amplifiers of the second set, respectively.

2. The signal driver of claim 1, further comprising a control circuit configured to open or close the first switch device and the set of one or more switch devices in accordance with a first mode of operation or a second mode of operation, respectively.

3. The signal driver of claim 1, further comprising a second switch device coupled between the first signal output and the second signal output.

4. The signal driver of claim 3, further comprising a control circuit configured to open or close the first switch device, the second switch device, and the set of one or more switch devices in accordance with a first mode of operation or a second mode of operation, respectively.

5. The signal driver of claim 1, wherein the second set of amplifiers includes a set of enable control inputs, respectively, and further comprising a control circuit configured to provide deasserted and asserted set of enable control signals to the set of enable control inputs in accordance with a first mode of operation or a second mode of operation, respectively.

6. The signal driver of claim 1, wherein:
one of the first set of amplifiers comprises a first set of amplification stages;
one of the second set of amplifiers comprises a second set of amplification stages; and
further comprising a second switch device coupled between two of the first set of amplification stages and two of the second set of amplification stages.

7. The signal driver of claim 6, further comprising a control circuit configured to open or close the first switch device, the second switch device, and the set of one or more switch devices in accordance with a first mode of operation or a second mode of operation, respectively.

8. The signal driver of claim 1, wherein:
one of the first set of amplifiers comprises a first differential operational transconductance amplifier (OTA);
one of the second set of amplifiers comprises a second differential OTA; and
the first switch device comprises first differential switch devices coupled between a first differential input of the first differential OTA and a second differential input of the second differential OTA.

9. The signal driver of claim 8, wherein one of the set of one or more switch devices comprises second differential switch devices coupled between a first differential output of the first differential OTA and a second differential output of the second differential OTA.

10. The signal driver of claim 9, further comprising a control circuit configured to open or close the first and second differential switch devices in accordance with a first mode of operation or a second mode of operation, respectively.

11. The signal driver of claim 1, wherein:
one of the first set of amplifiers comprises a first power amplifier (PA);
one of the second set of amplifiers comprises a second PA; and
one of the set of one or more switch devices comprises first differential switch devices coupled between a first differential input of the first PA and a second differential input of the second PA.

12. The signal driver of claim 11, further comprising second differential switch devices coupled between a first differential output of the first PA and a second differential output of the second PA.

13. The signal driver of claim 1, further comprising:
a first digital-to-analog converter (DAC) coupled between a first digital input and the first signal input;
a second DAC coupled between a second digital input of the second signal input; and
a second switch device coupled between the first digital input and the second digital input.

14. The signal driver of claim 13, further comprising a control circuit configured to open or close the first switch device, the second switch device, and the set of one or more switch devices in accordance with a first mode of operation or a second mode of operation, respectively.

15. A method of providing an output signal to a load, comprising:
amplifying an input signal using a first set of cascaded amplifiers to generate the output signal in accordance with a first mode of operation and a second mode of operation;
amplifying the input signal using a second set of cascaded amplifiers to generate the output signal in accordance with the second mode of operation but not the first mode of operation; and
coupling inputs and outputs of the first set of cascaded amplifiers to inputs and outputs of the second set of cascaded amplifiers in accordance with the second mode of operation, respectively.

16. The method of claim 15, further comprising decoupling the inputs and outputs of the first set of cascaded amplifiers from the inputs and outputs of the second set of cascaded amplifiers in accordance with the first mode of operation.

17. The method of claim 15, further comprising disabling the second set of cascaded amplifiers in accordance with the first mode of operation.

18. The method of claim 15, wherein a first last stage of the first set of cascaded amplifiers is enabled, and a second last stage of the second set of cascaded amplifiers is disabled in accordance with the second mode of operation.

19. The method of claim 15, further comprising coupling a first output of the first last stage of the first set of cascaded amplifiers to a second output of the second last stage of the second set of cascaded amplifiers in accordance with the second mode of operation.

20. The method of claim 15, wherein the input signal comprises an analog signal, and further comprising:
converting a digital signal to generate at least a portion of the analog signal; and
converting the digital signal to generate at least another portion of the analog signal.
